(19) United States
(12) Patent Application Publication
(10) Pub. No.: US 2019/0041895 A1
(43) Pub. Date: Feb. 7, 2019

(54) SINGLE CLOCK SOURCE FOR A MULTIPLE DIE PACKAGE

(71) Applicants: Yingyu Miao, Cupertino, CA (US); Gerald Pasdast, San Jose, CA (US); Peipei Wang, San Jose, CA (US); Mahesh Kumashikar, Bangalore (IN)

(72) Inventors: Yingyu Miao, Cupertino, CA (US); Gerald Pasdast, San Jose, CA (US); Peipei Wang, San Jose, CA (US); Mahesh Kumashikar, Bangalore (IN)

(21) Appl. No.: 15/952,169

(22) Filed: Apr. 12, 2018

(51) Int. Cl. G06F 1/10; H03K 5/15; H01L 23/66; H01L 25/065

(52) U.S. Cl. CPC G06F 1/10; H03K 5/1506; H01L 23/66; H01L 25/0657; H03L 7/06; H01L 2223/6627; H01L 2223/6661; H01L 2225/06527; H01L 2223/6638

(57) ABSTRACT

A processing device includes a package, a plurality of dies disposed on the package, where each die comprises a clock receiver, and a single common clock source to generate a common clock signal. The processing device also includes a clock distribution circuitry coupled to the single common clock source. The clock distribution circuitry distributes the common clock signal from the single common clock source to each of the plurality of dies individually. The clock distribution circuitry includes a first group of terminated transmission lines. The first group of terminated transmission lines includes a first terminated transmission line, a second terminated transmission line, and a first termination resistor coupled between the first terminated transmission line and the second terminated transmission line. The first terminated transmission line and the second terminated transmission line receive the common clock signal from the single common clock source.

### TECHNICAL FIELD

Embodiments of the disclosure relate generally to a common clocking scheme for a multiple die package.

### BACKGROUND

Electronic packages are increasingly becoming more populated with various components. Many of the components need to communicate with each other. In order for the components to properly communicate with one another they need to have matching clock signals. Additionally, the communication scheme causes latency in the communication signals between the various components which slows down the system. Some conventional methods attempt to provide matching clock signals between components, however, such conventional methods introduce undesirable latency which negatively affects system performance.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1A illustrates a block diagram of a multiple chip package having a common clock scheme according to various embodiments.

FIG. 1B illustrates a block diagram of a multiple chip package having a common clock scheme according to various embodiments.

FIG. 1C illustrates a block diagram of a multiple chip package having a common clock scheme according to various embodiments.

FIG. 1D illustrates a block diagram of chips stacked on top of one another in a package having a common clock scheme according to various embodiments.

FIG. 1E illustrates a block diagram of a single common clock source disposed on a package according to various embodiments.

FIG. 1F illustrates a block diagram of a single common clock source disposed on a die according to various embodiments.

FIG. 2 illustrates a block diagram of clock distribution circuitry coupled to a single common clock source according to various embodiments.

FIG. 3 illustrates a block diagram of clock distribution circuitry coupled to a single common clock source according to various embodiments.

FIG. 4 illustrates a block diagram of data flow from a first die to a second die having a single common clock signal according to various embodiments.

FIG. 5A is a block diagram illustrating a micro-architecture for a processor according to an embodiment of the disclosure.

FIG. 5B is a block diagram illustrating an in-order pipeline and a register renaming stage, out-of-order issue/execution pipeline according to an embodiment of the disclosure.

FIG. 6 is a block diagram illustrating a micro-architecture for a processor in accordance with one embodiment of the disclosure.

FIG. 7 is a block diagram illustrating a system in which an embodiment of the disclosure may be used.

FIG. 8 is a block diagram illustrating a system in which an embodiment of the disclosure may operate.

FIG. 9 is a block diagram illustrating a system in which an embodiment of the disclosure may operate.

FIG. 10 is a block diagram illustrating a System-on-a-Chip (SoC) according to an embodiment of the disclosure;

FIG. 11 is a block diagram illustrating a SoC design according to an embodiment of the disclosure; and

FIG. 12 illustrates a block diagram illustrating a computer system according to an embodiment of the disclosure.

### DETAILED DESCRIPTION

The embodiments described herein are directed to a single clock source for a multiple die package. As noted above, in some conventional systems, the communication scheme in a multiple die package causes undesirable latency in the communication signals between various components in the multiple die package. Some conventional systems are described below. In one conventional method, each die on a package includes its own phase-locked loop (PLL). Data sent from a first die to a second die goes through a first in, first out (FIFO) for clock domain crossing. This causes two cycles of latency. For latency critical transactions, the latency negatively impacts system performance. In another conventional method, a PLL from a first die is forwarded to a second die. This is used as the second die's clock source. In this scenario, jitter is introduced due to jitter accumulation from the clock path on the first die. In an additional conventional method, in a multiple chip package application, each PLL output clock buffer only drives one chip on the board. In this scenario, the buffer is able to drive a number of output buffers. Each clock tree dropoff point has a matching phase. However, this doesn't guarantee phase matching before entering each chip.

As will be described in further detail below, various embodiments described herein overcome this performance degradation. In general, a single common clock source is provided to the multiple dies in a package via clock distribution circuitry. As a result, each die in the package receive a common clock signal with reduced latency and the same or less jitter contribution as compared to conventional methods.

In various embodiments described herein a processing device includes a package, a plurality of dies disposed on the package, where each die comprises a clock receiver, and a single common clock source to generate a common clock signal. The processing device also includes a clock distribution circuitry coupled to the single common clock source. The clock distribution circuitry distributes the common clock signal from the single common clock source to each of the plurality of dies individually. The clock distribution circuitry includes a first group of terminated transmission lines. The first group of terminated transmission lines includes a first terminated transmission line, a second terminated transmission line, and a first termination resistor coupled between the first terminated transmission line and the second terminated transmission line. The first terminated transmission line and the second terminated transmission line receive the common clock signal from the single common clock source

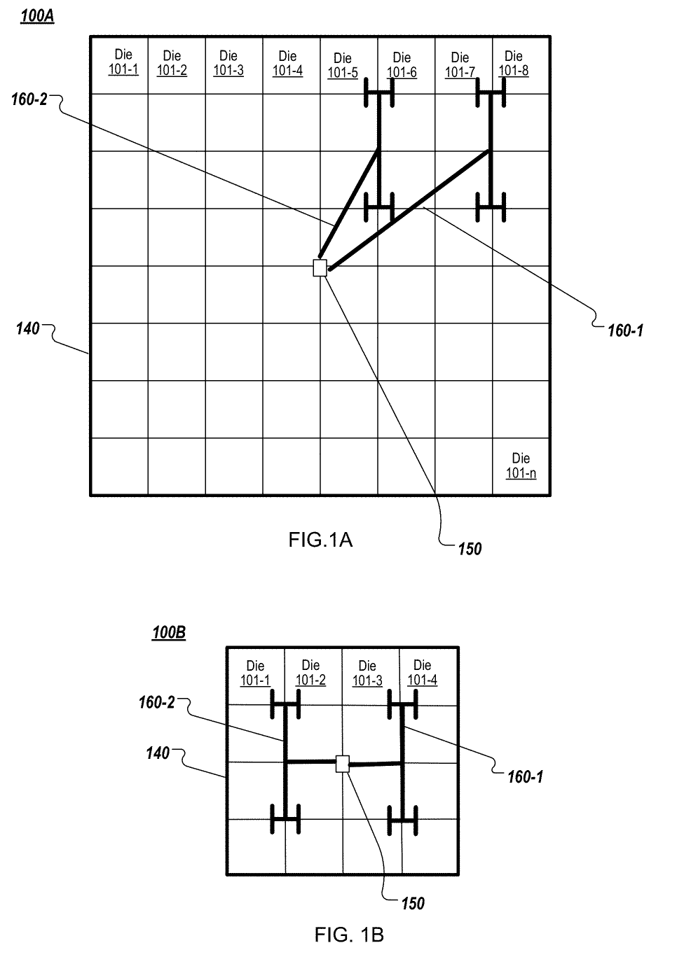

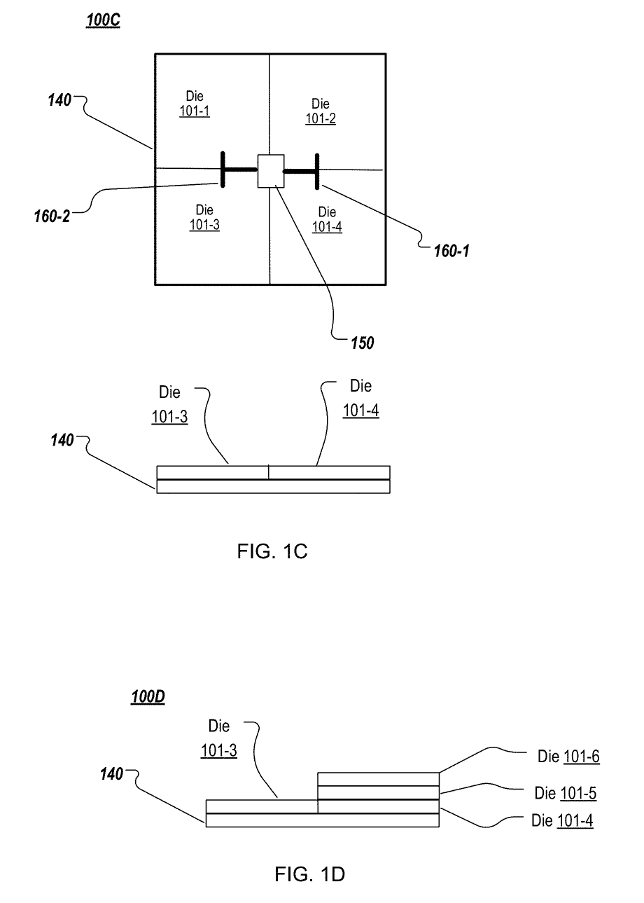

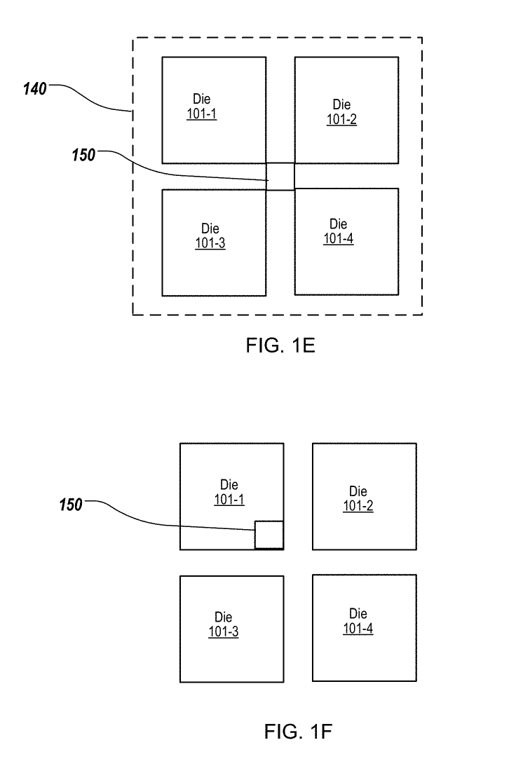

FIG. 1A illustrates a block diagram of package 100A according to various embodiments. Package 100A includes a plurality of die 101, also referred to as dielets (e.g., die 101-1 through die 100-n) disposed on substrate 140. FIG. 1A depicts 64 separate die. However, it should be appreciated that package 100A can include any number of die. For example, package 100A can include more or less than 64 die. The plurality of die can include various components. In one embodiment, a die is a core (e.g., processing core or graphics core).

Package 100A, in various embodiments, includes single common clock source 150. That is, package 100A includes only one common clock source. As such, each die 101 receives the same clock signal from the single common clock source. Single common clock source 150, in various embodiments, can be, but is not limited to, discrete resonator, discrete oscillator, a clock generator (e.g., phase-locked loop clock generator).

A single common clock source for the dies on the package results in at least two cycles of latency saving as compared to conventional methods. Additionally, a single common clock source, described herein, results in no jitter accumulation from supply noise on clock distribution. For example, estimated savings may be over 10 ps when compared to conventional methods of die repeater chain clock distribution. The common clock signal, from single common clock source 150, is transmitted to the die via transmission lines 160 (e.g., transmission lines 160-1 and 160-2). For the sake of clarity and simplicity, only two transmission lines are depicted in FIG. 1A. However, it should be appreciated that package 100A can include any number of transmission lines (in various routing schemes) such that the common clock signal is distributed to the die. As will be described in further detail below, the common clock signal from the single common clock source 150 is distributed to the die by way of clock distribution circuitry.

FIG. 1B illustrates a block diagram of package 100B according to various embodiments. Package 100B is similar to package 100A, as described herein. For example, package 100B includes substrate 140, single clock source 150, and transmission lines 160 coupled to die 101. As shown in FIG. 1B, package 100B includes sixteen die. It should be appreciated that package 100B can include more or less than sixteen die.

FIG. 1C illustrates a block diagram of package 100C according to various embodiments. Package 100C is similar to packages 100A and 100B, described herein. For example, package 100C includes substrate 140, single clock source 150, and transmission lines 160 coupled to die 101. The common clock signal is transmitted to the die via transmission lines 160 (e.g., transmission lines 160-1 and 160-2). As will be described in further detail below, the common clock signal from the single common clock source 150 is distributed to the die by way of clock distribution circuitry. As shown in FIG. 1C, package 100C includes four die. It should be appreciated that package 100C can include more or less than four die.

FIG. 1C also depicts a side-view of package 100C according to various embodiments. As shown in the side-view, die 101 on package 100C are disposed horizontally (with respect to one another) on substrate 140.

FIG. 1D depicts a side-view of package 100D accordingly to various embodiments. Package 100D is similar to packages 100A-C as described herein. As shown in FIG. 1D, die 101 are disposed horizontally to one another (e.g., die 101-3 is disposed horizontally to die 101-5). Additionally, die 101 are disposed vertically with respect to one another. For example, die 101-5 is stacked on top of die 101-4, and die 101-6 is stacked on top of die 101-6. In the embodiments where dies are stacked on each other, each of the stacked die receives the common clock signal from the single common clock source via clock distribution circuitry. It should be appreciated that package 100D can have multiple locations of stacked die. For example, two, three, or four (or more) dies may be stacked on top of one another at one location on the package or multiple locations package.

FIG. 1E depicts single common clock source 150 according to various embodiments. As shown in FIG. 1E, single common clock source 150 is disposed on substrate 140 (e.g., on a separate chip other than a die). In one embodiment, single common clock source 150 is centered on the package. That is, the clock source is disposed at the center area of the package.

FIG. 1F depicts single common clock source 150 according to various embodiments. A shown in FIG. 1F, single common clock source 150 is disposed on a die on the package. In one embodiment, the die that the single common clock source is disposed upon is in the center area of the package.

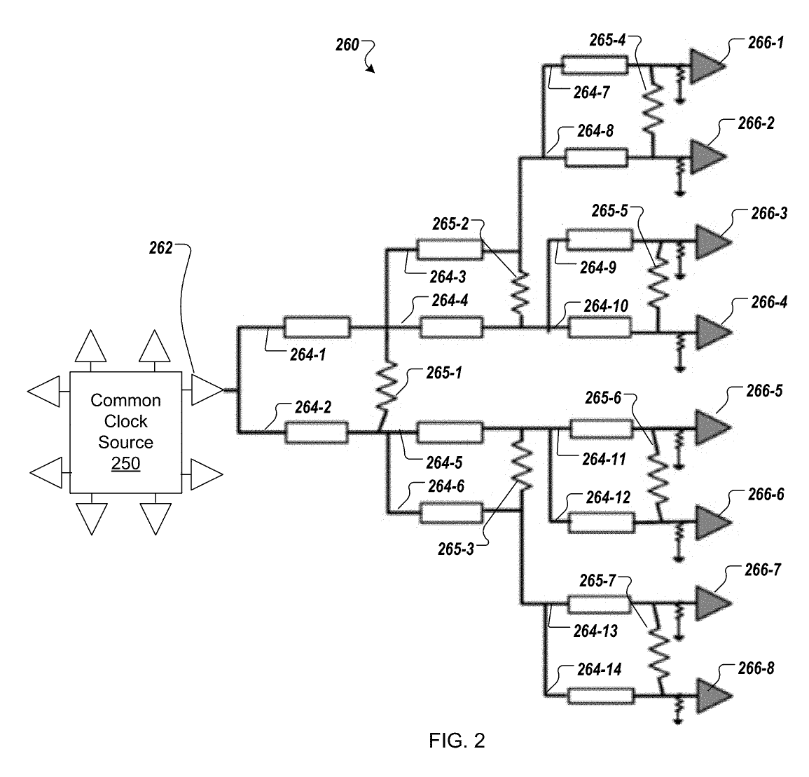

FIG. 2 depicts a block diagram of common clock source 250 coupled to clock distribution circuitry 260 according to various embodiments. As will be described in further detail below, clock distribution circuitry 260 distributes the signal from the common clock source to the die. Clock distribution circuitry 260 can be, but is not limited to, a fan-out buffer, complementary metal-oxide-semiconductor (CMOS) clock buffer, LVCOMS, LVDS, and CML. Common clock source 250, in various embodiments, is similar to common clock source 150 described herein.

Clock distribution circuitry 260, in various embodiments, includes line driver 262, transmission lines 264, termination resistors 265 and drop points 266. For the sake of clarity and simplicity, FIG. 2 depicts one clock distribution circuitry 260 that includes eight drop points, where each drop point is configured to connect to a clock receiver of a die. However, it should be appreciated that common clock source 250, in various embodiments, can be coupled to eight separate clock distribution circuitry 260 such that there are 64 drop points 266.

Clock distribution circuitry 260, in one embodiment, includes a first series of transmission lines. For example, the first series of transmission lines includes a first group of transmission lines 264-1 and 264-2 with termination resistor 265-1 coupled between the transmission lines. Transmission lines 264-1 and 264-2 each receive a clock signal from common clock source 250. Transmission lines 264-1 and 264-2 split the clock signal from common clock source into two separate signals.

Clock distribution circuitry 260, in one embodiment, includes a second series of transmission lines. For example, the second series of transmission lines includes a second group of transmission lines 264-3 and 264-4 (with termination resistor 265-2 coupled between the transmission lines), and a third group of transmission lines 264-5 and 264-6 (with termination resistor 265-3 coupled between the transmission lines). The second group of transmission lines 264-3 and 264-4 are coupled to transmission line 264-1 and each receive the clock signal from common clock source 250 via transmission line 264-1. Transmission lines 264-3 and 264-4 split the clock signal from transmission line 264-1 into two separate signals. Similarly, the third group of transmission lines 264-5 and 264-6 are coupled to transmission line 264-2 and each receives the clock signal from common clock source 250 via transmission line 264-2. Transmission lines 264-5 and 264-6 split the clock signal from transmission line 264-2 into two separate signals. Accordingly, the second series of transmission lines splits the common clock signal into four separate clock signals (via transmission lines 264-3 through 264-6).

Clock distribution circuitry 260, in one embodiment, includes a third series of transmission lines. For example, the third series of transmission lines includes a fourth group of transmission lines 264-7 and 264-8 (with termination resistor 265-4 coupled between the transmission lines), a fifth group of transmission lines 264-9 and 264-10 (with termination resistor 265-5 coupled between the transmission lines), a sixth group of transmission lines 264-11 and 264-12 (with termination resistor 265-6 coupled between the transmission lines), and a seventh group of transmission lines 264-13 and 264-14 (with termination resistor 265-7 coupled between the transmission lines). The fourth group of transmission lines 264-7 and 264-8 are coupled to transmission line 264-3 and each receives the clock signal from common clock source 250 via transmission line 264-3. Transmission lines 264-7 and 264-8 split the clock signal from transmission line 264-3 into two separate signals. Similarly, the fifth group, sixth group and seventh group of transmission lines are respectively coupled to a transmission line from the second series of transmission lines and split the received common clock signal into two separate common clock signals, respectively. Accordingly, the third series of transmission lines splits the common clock signal into eight separate clock signals (via transmission lines from the second series of transmission lines).

In various embodiments, each transmission line in the third series of transmission lines is coupled to a drop point 266. Each drop point is adapted to be coupled to a clock receiver of a die in a package. As such, source signal from common clock source 250 is distributed to eight different dies. As described above, common clock source 250 is capable of being coupled to eight different clock distribution circuitry 260. Accordingly, common clock source 250 is able to have its clock signal distributed to 64 different dies in a package (e.g., package 100A) via clock distribution circuitry 260.

In one embodiment, clock distribution circuitry 260 includes two series of transmission lines, as described above (and does not include the third series of transmission lines). Accordingly, the second series of transmission lines of clock distribution circuitry 260 splits the common clock signal into four separate clock signals (via transmission lines 264-3 through 264-6). Each of the transmission lines in the second series of transmission lines is coupled to four drop points 266, respectively. Moreover, each of the four drop points are coupled to four dies in the package. As such, the clock signal from common clock source is distributed to four dies on the package. In one embodiment, common clock source 250 is capable to being coupled to four different clock distribution circuitry 260. Accordingly, a common clock source 250 is able to have its clock signal distributed to sixteen different dies in a package (e.g., package 100B) via clock distribution circuitry 260.

In one embodiment, clock distribution circuitry 260 includes the first series of transmission lines, as described above (and does not include the second or third series of transmission lines). Accordingly, the first series of transmission lines of clock distribution circuitry 260 splits the common clock signal into two separate clock signals (via transmission lines 264-1 and 264-2). Each of the transmission lines in the first series of transmission lines is coupled to a drop point 266. Moreover, each of the drop points are coupled to dies in the package. As such, the clock signal from the common clock source is distributed to two dies on the package. In one embodiment, common clock source 250 is capable to being coupled to two different clock distribution circuitry 260. Accordingly, a common clock source 250 is able to have its clock signal distributed to four different dies in a package (e.g., package 100C) via clock distribution circuitry 260.

Clock distribution circuitry 260, in one embodiment, as shown in FIG. 2, is symmetrical. That is, the first series splits the clock signal into two separate signals, the second series splits the clock signal into four separate signals, the third series splits the clock signal into eight separate signals and so on. In other words, clock distribution circuitry 260 provides for an even number of fan outs. In one embodiment, clock distribution circuitry 260 can distribute clock signals to die package that includes an asymmetrical or odd number of dies. For example, referring to FIG. 1, package 100A includes 63 active die. However, one die (e.g., 101-7) is a dummy die. Clock distribution circuitry 260 can distribute 63 clock signals to the 63 active die and also provide a clock signal to the dummy die.

Clock distribution circuitry 260, in one embodiment, does not include, line driver 262. For example, when clock distribution circuitry 260 includes the first series of transmission lines, as described above (and does not include the second or third series of transmission lines), then the signal from common clock source 250 may be transmitted to the dies without the need for a line driver.

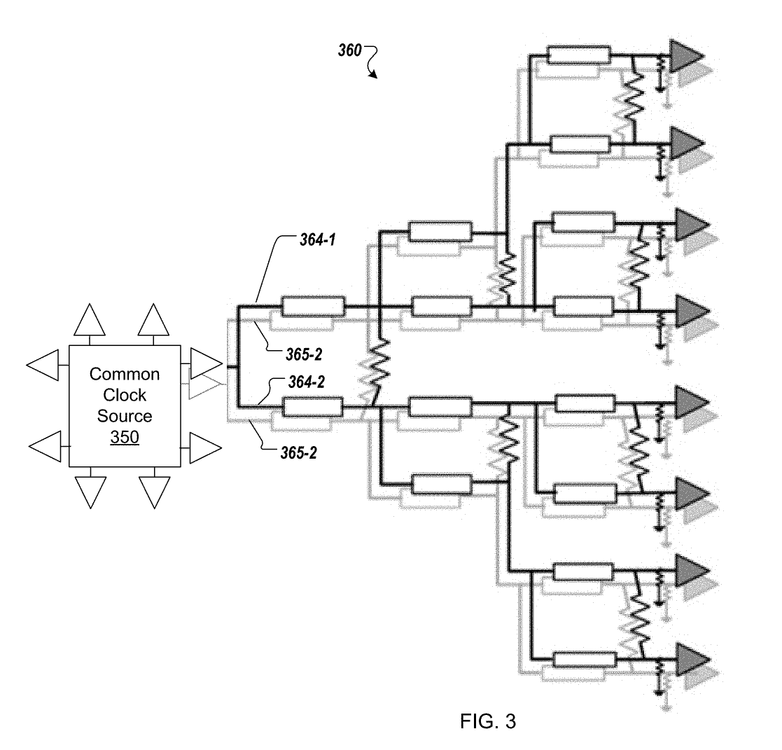

In various embodiments, each of the transmission lines in clock distribution circuitry 260 are terminated. Each of the transmission lines, in various embodiments, are passive transmission lines. In one embodiment, each of the transmission lines in clock distribution circuitry 260 are a single-ended transmission line (e.g., FIG. 2). Alternatively, in various embodiments, FIG. 3 depicts each of the transmission lines in clock distribution circuitry 360 (coupled to common clock source 350) are differential-pair transmission lines. For example, transmission lines 364-1 and 365-2 are a differential pair, and transmission lines 364-2 and 365-2 are a differential pair.

It should be appreciated that a transmission line may include one or more conductors or electrodes between two or more components. The transmission line may be made up of a pair of conductors, referred to as differential transmission lines, over which differential signals are transmitted. Alternatively, the transmission line may be a single conductor, referred to as a single-ended transmission line, over which signals are transmitted.

It should also be appreciated that a transmission line/signal path does not go through another die. That is, there are no intervening dies between the single clock source and any one of the plurality of dies. For example, the clock signal is not a signal that is received at a first die and forwarded along a path to a second die.

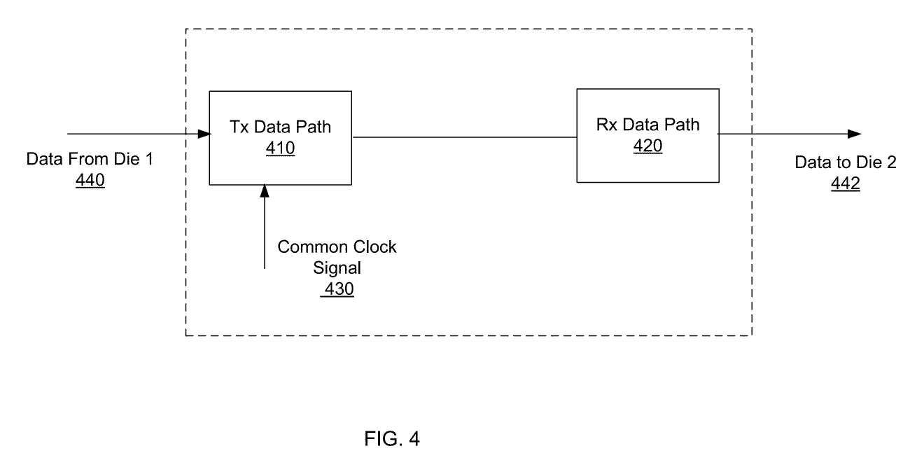

FIG. 4 is a block diagram of data flow from a first die (e.g., die 101-4) to a second die (e.g., die 101-5) having a common clock signal. For example, data 440 is transmitted from Tx data path 410 to Rx data path 420, where the data is transmitted from a first die to a second die. At the Tx data path 410, common clock signal 430 is received at Tx data path 410. The common clock signal 430 is received from a single common clock source 150 of the package.

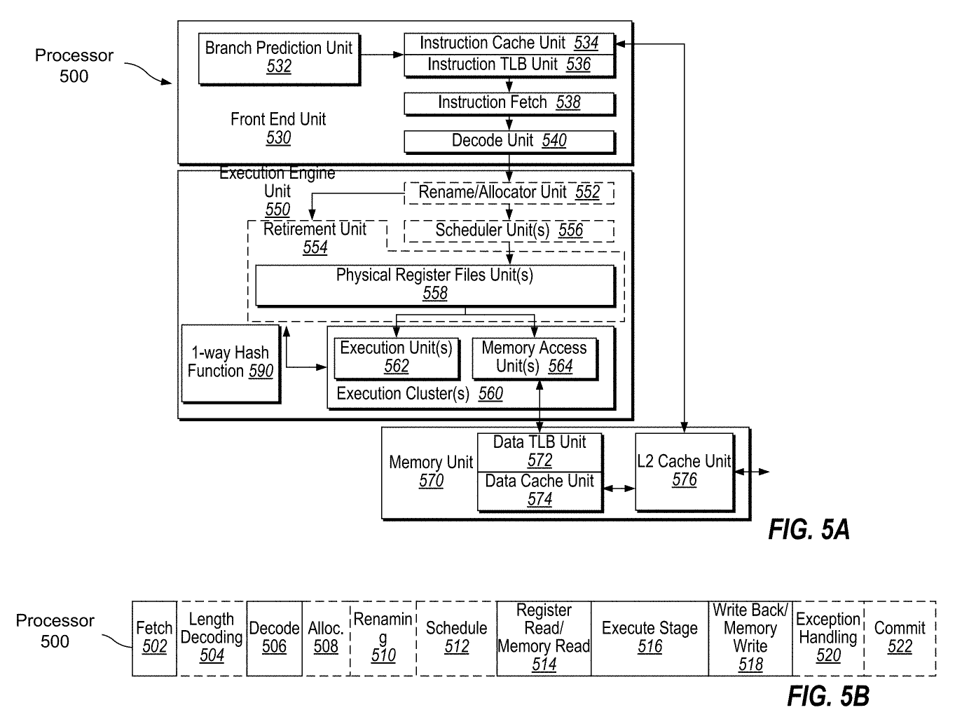

FIG. 5A is a block diagram illustrating a micro-architecture for a processor 500 that implements the processing device including heterogeneous cores in accordance with one embodiment of the disclosure. Specifically, processor 500 depicts an in-order architecture core and a register renaming logic, out-of-order issue/execution logic to be included in a processor according to at least one embodiment of the disclosure.

Processor 500 includes a front end unit 530 coupled to an execution engine unit 550, and both are coupled to a memory unit 570. The processor 500 may include a reduced instruction set computing (RISC) core, a complex instruction set computing (CISC) core, a very long instruction word (VLIW) core, or a hybrid or alternative core type. As yet another option, processor 500 may include a special-purpose core, such as, for example, a network or communication core, compression engine, graphics core, or the like. In one embodiment, processor 500 may be a multi-core processor or may be part of a multi-processor system.

The front end unit 530 includes a branch prediction unit 532 coupled to an instruction cache unit 534, which is coupled to an instruction translation lookaside buffer (TLB) 536, which is coupled to an instruction fetch unit 538, which is coupled to a decode unit 540. The decode unit 540 (also known as a decoder) may decode instructions, and generate as an output one or more micro-operations, micro-code entry points, microinstructions, other instructions, or other control signals, which are decoded from, or which otherwise reflect, or are derived from, the original instructions. The decoder 540 may be implemented using various different mechanisms. Examples of suitable mechanisms include, but are not limited to, look-up tables, hardware implementations, programmable logic arrays (PLAs), microcode read only memories (ROMs), etc. The instruction cache unit 534 is further coupled to the memory unit 570. The decode unit 540 is coupled to a rename/allocator unit 552 in the execution engine unit 550.

The execution engine unit 550 includes the rename/allocator unit 552 coupled to a retirement unit 554 and a set of one or more scheduler unit(s) 556. The scheduler unit(s) 556 represents any number of different schedulers, including reservations stations (RS), central instruction window, etc. The scheduler unit(s) 556 is coupled to the physical register file(s) unit(s) 558. Each of the physical register file(s) units 558 represents one or more physical register files, different ones of which store one or more different data types, such as scalar integer, scalar floating point, packed integer, packed floating point, vector integer, vector floating point, etc., status (e.g., an instruction pointer that is the address of the next instruction to be executed), etc. The physical register file(s) unit(s) 558 is overlapped by the retirement unit 554 to illustrate various ways in which register renaming and out-of-order execution may be implemented (e.g., using a reorder buffer(s) and a retirement register file(s), using a future file(s), a history buffer(s), and a retirement register file(s); using a register maps and a pool of registers; etc.).

In one implementation, processor 500 may be a die in FIG. 1. Generally, the architectural registers are visible from the outside of the processor or from a programmer's perspective. The registers are not limited to any known particular type of circuit. Various different types of registers are suitable as long as they are capable of storing and providing data as described herein. Examples of suitable registers include, but are not limited to, dedicated physical registers, dynamically allocated physical registers using register renaming, combinations of dedicated and dynamically allocated physical registers, etc. The retirement unit 554 and the physical register file(s) unit(s) 558 are coupled to the execution cluster(s) 560. The execution cluster(s) 560 includes a set of one or more execution units 562 and a set of one or more memory access units 564. The execution units 562 may perform various operations (e.g., shifts, addition, subtraction, multiplication) and operate on various types of data (e.g., scalar floating point, packed integer, packed floating point, vector integer, vector floating point).

While some embodiments may include a number of execution units dedicated to specific functions or sets of functions, other embodiments may include only one execution unit or multiple execution units that all perform all functions. The scheduler unit(s) 556, physical register file(s) unit(s) 558, and execution cluster(s) 560 are shown as being possibly plural because certain embodiments create separate pipelines for certain types of data/operations (e.g., a scalar integer pipeline, a scalar floating point/packed integer/packed floating point/vector integer/vector floating point pipeline, and/or a memory access pipeline that each have their own scheduler unit, physical register file(s) unit, and/or execution cluster—and in the case of a separate memory access pipeline, certain embodiments are implemented in which only the execution cluster of this pipeline has the memory access unit(s) 564). It should also be understood that where separate pipelines are used, one or more of these pipelines may be out-of-order issue/execution and the rest in-order.

The set of memory access units 564 is coupled to the memory unit 570, which may include a data prefetcher 580, a data TLB unit 572, a data cache unit (DCU) 574, and a level 2 (L2) cache unit 576, to name a few examples. In some embodiments DCU 574 is also known as a first level data cache (L1 cache). The DCU 574 may handle multiple outstanding cache misses and continue to service incoming stores and loads. It also supports maintaining cache coherency. The data TLB unit 572 is a cache used to improve virtual address translation speed by mapping virtual and physical address spaces. In one exemplary embodiment, the memory access units 564 may include a load unit, a store address unit, and a store data unit, each of which is coupled to the data TLB unit 572 in the memory unit 570. The L2 cache unit 576 may be coupled to one or more other levels of cache and eventually to a main memory.

In one embodiment, the data prefetcher 580 speculatively loads/prefetches data to the DCU 574 by automatically predicting which data a program is about to consume. Prefeteching may refer to transferring data stored in one memory location of a memory hierarchy (e.g., lower level caches or memory) to a higher-level memory location that is closer (e.g., yields lower access latency) to the processor before the data is actually demanded by the processor. More specifically, prefetching may refer to the early retrieval of data from one of the lower level caches/memory to a data cache and/or prefetch buffer before the processor issues a demand for the specific data being returned.

The processor 500 may support one or more instructions sets (e.g., the x86 instruction set (with some extensions that have been added with newer versions); the MIPS instruction set of MIPS Technologies of Sunnyvale, Calif.; the ARM instruction set (with optional additional extensions such as NEON) of ARM Holdings of Sunnyvale, Calif.).

It should be understood that the core may support multithreading (executing two or more parallel sets of operations or threads), and may do so in a variety of ways including time sliced multithreading, simultaneous multithreading (where a single physical core provides a logical core for each of the threads that physical core is simultaneously multithreading), or a combination thereof (e.g., time sliced fetching and decoding and simultaneous multithreading thereafter such as in the Intel® Hyperthreading technology).

While register renaming is described in the context of out-of-order execution, it should be understood that register renaming may be used in an in-order architecture. While the illustrated embodiment of the processor also includes a separate instruction and data cache units and a shared L2 cache unit, alternative embodiments may have a single internal cache for both instructions and data, such as, for example, a Level 1 (L1) internal cache, or multiple levels of internal cache. In some embodiments, the system may include a combination of an internal cache and an external cache that is external to the core and/or the processor. Alternatively, all of the cache may be external to the core and/or the processor.

FIG. 5B is a block diagram illustrating an in-order pipeline and a register renaming stage, out-of-order issue/execution pipeline implemented by processor 500 of FIG. 5A according to some embodiments of the disclosure. The solid lined boxes in FIG. 5B illustrate an in-order pipeline, while the dashed lined boxes illustrates a register renaming, out-of-order issue/execution pipeline. In FIG. 5B, a processor 500 as a pipeline includes a fetch stage 502, a length decode stage 504, a decode stage 506, an allocation stage 508, a renaming stage 510, a scheduling (also known as a dispatch or issue) stage 512, a register read/memory read stage 514, an execute stage 516, a write back/memory write stage 518, an exception handling stage 522, and a commit stage 524. In some embodiments, the ordering of stages 502-524 may be different than illustrated and are not limited to the specific ordering shown in FIG. 5B.

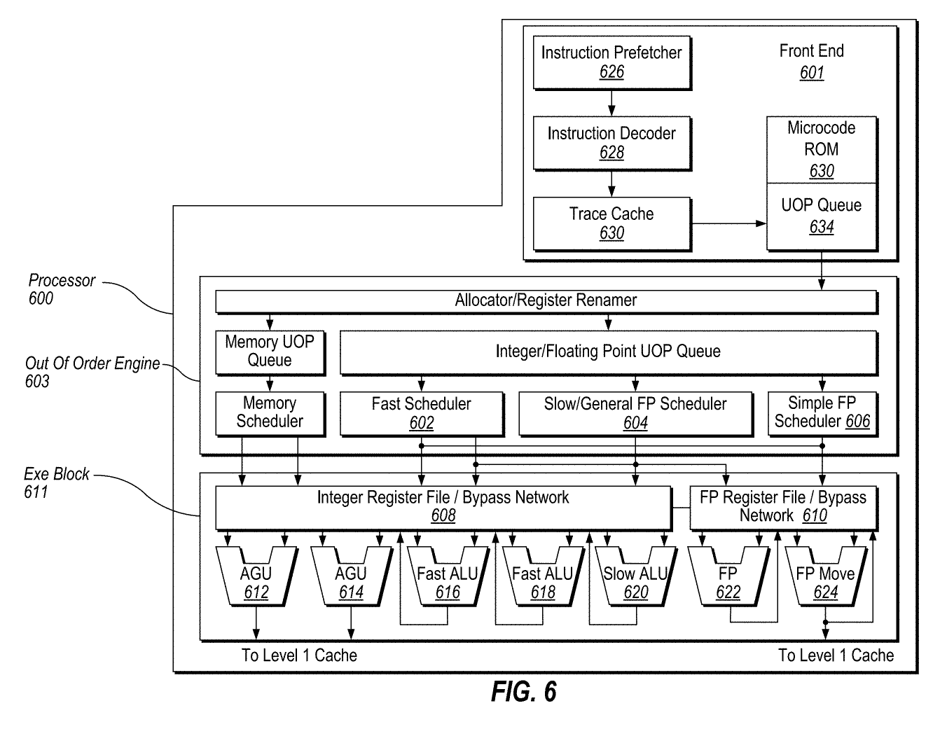

FIG. 6 illustrates a block diagram of the micro-architecture for a processor 600 that includes hybrid cores in accordance with one embodiment of the disclosure. In some embodiments, an instruction in accordance with one embodiment can be implemented to operate on data elements having sizes of byte, word, doubleword, quadword, etc., as well as datatypes, such as single and double precision integer and floating point datatypes. In one embodiment the in-order front end 601 is the part of the processor 600 that fetches instructions to be executed and prepares them to be used later in the processor pipeline.

The front end 601 may include several units. In one embodiment, the instruction prefetcher 626 fetches instructions from memory and feeds them to an instruction decoder 628 which in turn decodes or interprets them. For example, in one embodiment, the decoder decodes a received instruction into one or more operations called “micro-instructions” or “micro-operations” (also called micro op or uops) that the machine can execute. In other embodiments, the decoder parses the instruction into an opcode and corresponding data and control fields that are used by the micro-architecture to perform operations in accordance with one embodiment. In one embodiment, the trace cache 630 takes decoded uops and assembles them into program ordered sequences or traces in the uop queue 634 for execution. When the trace cache 630 encounters a complex instruction, the microcode ROM 632 provides the uops needed to complete the operation.

Some instructions are converted into a single micro-op, whereas others need several micro-ops to complete the full operation. In one embodiment, if more than four micro-ops are needed to complete an instruction, the decoder 628 accesses the microcode ROM 632 to do the instruction. For one embodiment, an instruction can be decoded into a small number of micro ops for processing at the instruction decoder 628. In another embodiment, an instruction can be stored within the microcode ROM 632 should a number of micro-ops be needed to accomplish the operation. The trace cache 630 refers to an entry point programmable logic array (PLA) to determine a correct micro-instruction pointer for reading the micro-code sequences to complete one or more instructions in accordance with one embodiment from the micro-code ROM 632. After the microcode ROM 632 finishes sequencing micro-ops for an instruction, the front end 601 of the machine resumes fetching micro-ops from the trace cache 630.

The out-of-order execution engine 603 is where the instructions are prepared for execution. The out-of-order execution logic has a number of buffers to smooth out and re-order the flow of instructions to optimize performance as they go down the pipeline and get scheduled for execution. The allocator logic allocates the machine buffers and resources that each uop needs in order to execute. The register renaming logic renames logic registers onto entries in a register file. The allocator also allocates an entry for each uop in one of the two uop queues, one for memory operations and one for non-memory operations, in front of the instruction schedulers: memory scheduler, fast scheduler 602, slow/general floating point scheduler 604, and simple floating point scheduler 606. The uop schedulers 602, 604, 606, determine when a uop is ready to execute based on the readiness of their dependent input register operand sources and the availability of the execution resources the uops need to complete their operation. The fast scheduler 602 of one embodiment can schedule on each half of the main clock cycle while the other schedulers can only schedule once per main processor clock cycle. The schedulers arbitrate for the dispatch ports to schedule uops for execution.

Register files 608, 610, sit between the schedulers 602, 604, 606, and the execution units 612, 614, 616, 618, 620, 622, 624 in the execution block 611. There is a separate register file 608, 610, for integer and floating point operations, respectively. Each register file 608, 610, of one embodiment also includes a bypass network that can bypass or forward just completed results that have not yet been written into the register file to new dependent uops. The integer register file 608 and the floating point register file 610 are also capable of communicating data with the other. For one embodiment, the integer register file 608 is split into two separate register files, one register file for the low order 32 bits of data and a second register file for the high order 32 bits of data. The floating point register file 610 of one embodiment has 128 bit wide entries because floating point instructions typically have operands from 64 to 128 bits in width.

The execution block 611 contains the execution units 612, 614, 616, 618, 620, 622, 624, where the instructions are actually executed. This section includes the register files 608, 610, that store the integer and floating point data operand values that the micro-instructions need to execute. The processor 600 of one embodiment is comprised of a number of execution units: address generation unit (AGU) 612, AGU 614, fast ALU 616, fast ALU 618, slow ALU 620, floating point ALU 622, floating point move unit 624. For one embodiment, the floating point execution blocks 622, 624, execute floating point, MMX, SIMD, and SSE, or other operations. The floating point ALU 622 of one embodiment includes a 64 bit by 64 bit floating point divider to execute divide, square root, and remainder micro-ops. For embodiments of the present disclosure, instructions involving a floating point value may be handled with the floating point hardware.

In one embodiment, the ALU operations go to the high-speed ALU execution units 616, 618. The fast ALUs 616, 618, of one embodiment can execute fast operations with an effective latency of half a clock cycle. For one embodiment, most complex integer operations go to the slow ALU 620 as the slow ALU 620 includes integer execution hardware for long latency type of operations, such as a multiplier, shifts, flag logic, and branch processing. Memory load/store operations are executed by the AGUs 612, 614. For one embodiment, the integer ALUs 616, 618, 620, are described in the context of performing integer operations on 64 bit data operands. In alternative embodiments, the ALUs 616, 618, 620, can be implemented to support a variety of data bits including 16, 32, 128, 256, etc. Similarly, the floating point units 622, 624, can be implemented to support a range of operands having bits of various widths. For one embodiment, the floating point units 622, 624, can operate on 128 bits wide packed data operands in conjunction with SIMD and multimedia instructions.

In one embodiment, the uops schedulers 602, 604, 606, dispatch dependent operations before the parent load has finished executing. As uops are speculatively scheduled and executed in processor 600, the processor 600 also includes logic to handle memory misses. If a data load misses in the data cache, there can be dependent operations in flight in the pipeline that have left the scheduler with temporarily incorrect data. A replay mechanism tracks and re-executes instructions that use incorrect data. Only the dependent operations need to be replayed and the independent ones are allowed to complete. The schedulers and replay mechanism of one embodiment of a processor are also designed to catch instruction sequences for text string comparison operations.

The processor 600 also includes logic to implement store address prediction for memory disambiguation according to embodiments of the disclosure. In one embodiment, the execution block 611 of processor 600 may include a store address predictor (not shown) for implementing store address prediction for memory disambiguation.

The term “registers” may refer to the on-board processor storage locations that are used as part of instructions to identify operands. In other words, registers may be those that are usable from the outside of the processor (from a programmer's perspective). However, the registers of an embodiment should not be limited in meaning to a particular type of circuit. Rather, a register of an embodiment is capable of storing and providing data, and performing the functions described herein. The registers described herein can be implemented by circuitry within a processor using any number of different techniques, such as dedicated physical registers, dynamically allocated physical registers using register renaming, combinations of dedicated and dynamically allocated physical registers, etc. In one embodiment, integer registers store thirty-two bit integer data. A register file of one embodiment also contains eight multimedia SIMD registers for packed data.

For the discussions below, the registers are understood to be data registers designed to hold packed data, such as 64 bits wide MMXTM registers (also referred to as ‘mm’ registers in some instances) in microprocessors enabled with MMX technology from Intel Corporation of Santa Clara, Calif. These MMX registers, available in both integer and floating point forms, can operate with packed data elements that accompany SIMD and SSE instructions. Similarly, 128 bits wide XMM registers relating to SSE2, SSE3, SSE4, or beyond (referred to generically as “SSEx”) technology can also be used to hold such packed data operands. In one embodiment, in storing packed data and integer data, the registers do not need to differentiate between the two data types. In one embodiment, integer and floating point are either contained in the same register file or different register files. Furthermore, in one embodiment, floating point and integer data may be stored in different registers or the same registers.

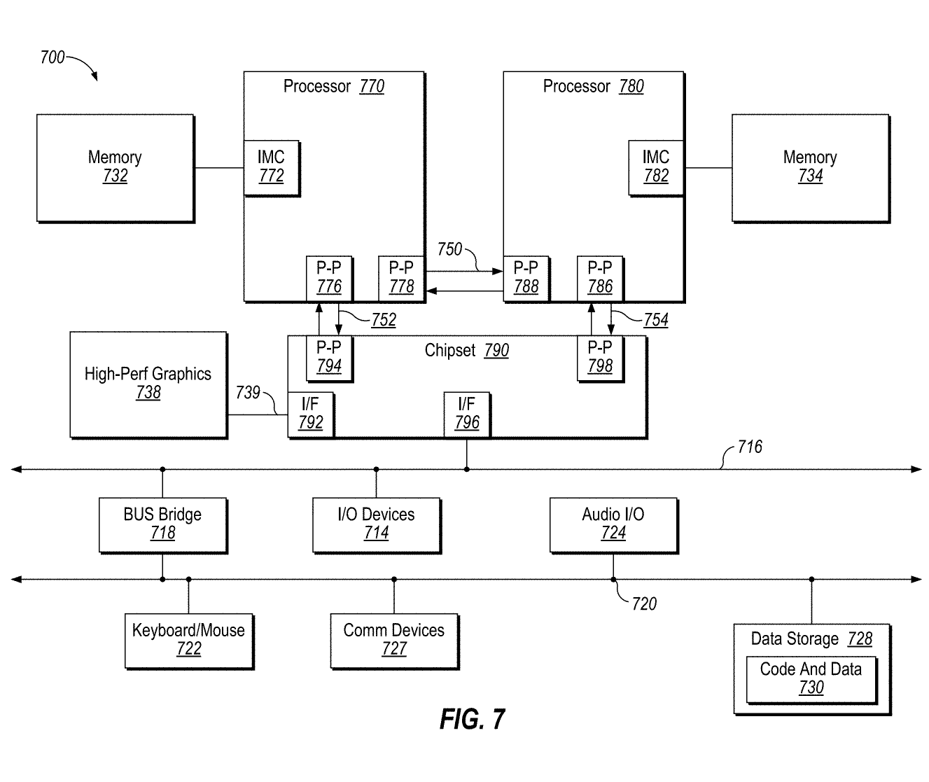

Referring now to FIG. 7, shown is a block diagram illustrating a system 700 in which an embodiment of the disclosure may be used. As shown in FIG. 7, multiprocessor system 700 is a point-to-point interconnect system, and includes a first processor 770 and a second processor 780 coupled via a point-to-point interconnect 750. While shown with only two processors 770, 780, it is to be understood that the scope of embodiments of the disclosure is not so limited. In other embodiments, one or more additional processors may be present in a given processor. In one embodiment, the multiprocessor system 700 may implement hybrid cores as described herein.

Processors 770 and 780 are shown including integrated memory controller units 772 and 782, respectively. Processor 770 also includes as part of its bus controller units point-to-point (P-P) interfaces 776 and 778; similarly, second processor 780 includes P-P interfaces 786 and 788. Processors 770, 780 may exchange information via a point-to-point (P-P) interface 750 using P-P interface circuits 778, 788. As shown in FIG. 7, IMCs 772 and 782 couple the processors to respective memories, namely a memory 732 and a memory 734, which may be portions of main memory locally attached to the respective processors.

Processors 770, 780 may each exchange information with a chipset 790 via individual P-P interfaces 752, 754 using point to point interface circuits 776, 794, 786, 798. Chipset 790 may also exchange information with a high-performance graphics circuit 738 via a high-performance graphics interface 739.

A shared cache (not shown) may be included in either processor or outside of both processors, yet connected with the processors via P-P interconnect, such that either or both processors' local cache information may be stored in the shared cache if a processor is placed into a low power mode.

Chipset 790 may be coupled to a first bus 716 via an interface 796. In one embodiment, first bus 716 may be a Peripheral Component Interconnect (PCI) bus, or a bus such as a PCI Express bus or another third generation I/O interconnect bus, although the scope of the present disclosure is not so limited.

As shown in FIG. 7, various I/O devices 714 may be coupled to first bus 716, along with a bus bridge 718 which couples first bus 716 to a second bus 720. In one embodiment, second bus 720 may be a low pin count (LPC) bus. Various devices may be coupled to second bus 720 including, for example, a keyboard and/or mouse 722, communication devices 727 and a storage unit 728 such as a disk drive or other mass storage device which may include instructions/code and data 730, in one embodiment. Further, an audio I/O 724 may be coupled to second bus 720. Note that other architectures are possible. For example, instead of the point-to-point architecture of FIG. 7, a system may implement a multi-drop bus or other such architecture.

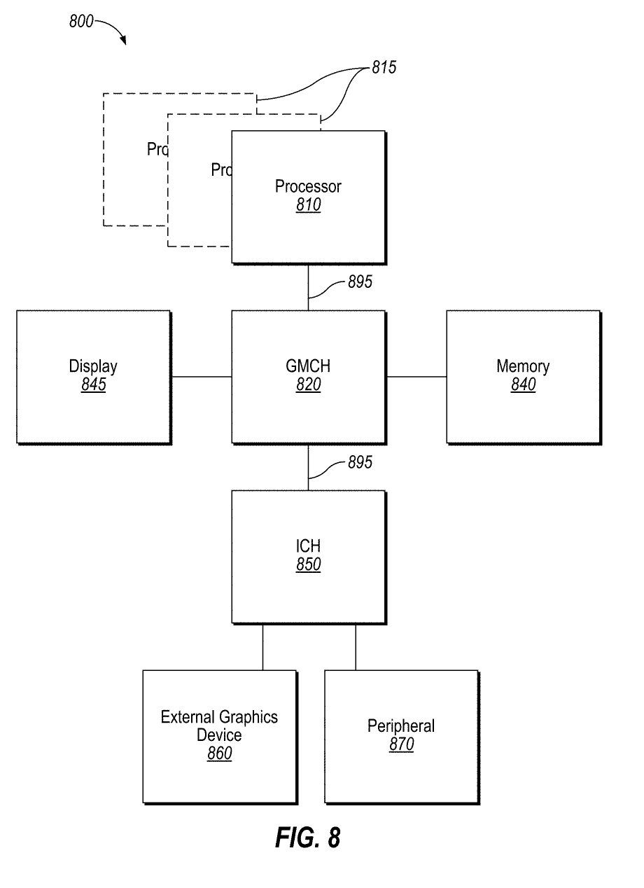

Referring now to FIG. 8, shown is a block diagram of a system 800 in which one embodiment of the disclosure may operate. The system 800 may include one or more processors 810, 815, which are coupled to graphics memory controller hub (GMCH) 820. The optional nature of additional processors 815 is denoted in FIG. 8 with broken lines. In one embodiment, processors 810, 815 implement hybrid cores according to embodiments of the disclosure.

Each processor 810, 815 may be some version of the circuit, integrated circuit, processor, and/or silicon integrated circuit as described above. However, it should be noted that it is unlikely that integrated graphics logic and integrated memory control units would exist in the processors 810, 815. FIG. 8 illustrates that the GMCH 820 may be coupled to a memory 840 that may be, for example, a dynamic random access memory (DRAM). The DRAM may, for at least one embodiment, be associated with a non-volatile cache.

The GMCH 820 may be a chipset, or a portion of a chipset. The GMCH 820 may communicate with the processor(s) 810, 815 and control interaction between the processor(s) 810, 815 and memory 840. The GMCH 820 may also act as an accelerated bus interface between the processor(s) 810, 815 and other elements of the system 800. For at least one embodiment, the GMCH 820 communicates with the processor(s) 810, 815 via a multi-drop bus, such as a frontside bus (FSB) 895.

Furthermore, GMCH 820 is coupled to a display 845 (such as a flat panel or touchscreen display). GMCH 820 may include an integrated graphics accelerator. GMCH 820 is further coupled to an input/output (I/O) controller hub (ICH) 850, which may be used to couple various peripheral devices to system 800. Shown for example in the embodiment of FIG. 8 is an external graphics device 860, which may be a discrete graphics device, coupled to ICH 850, along with another peripheral device 870.

Alternatively, additional or different processors may also be present in the system 800. For example, additional processor(s) 815 may include additional processors(s) that are the same as processor 810, additional processor(s) that are heterogeneous or asymmetric to processor 810, accelerators (such as, e.g., graphics accelerators or digital signal processing (DSP) units), field programmable gate arrays, or any other processor. There can be a variety of differences between the processor(s) 810, 815 in terms of a spectrum of metrics of merit including architectural, micro-architectural, thermal, power consumption characteristics, and the like. These differences may effectively manifest themselves as asymmetry and heterogeneity amongst the processors 810, 815. For at least one embodiment, the various processors 810, 815 may reside in the same die package.

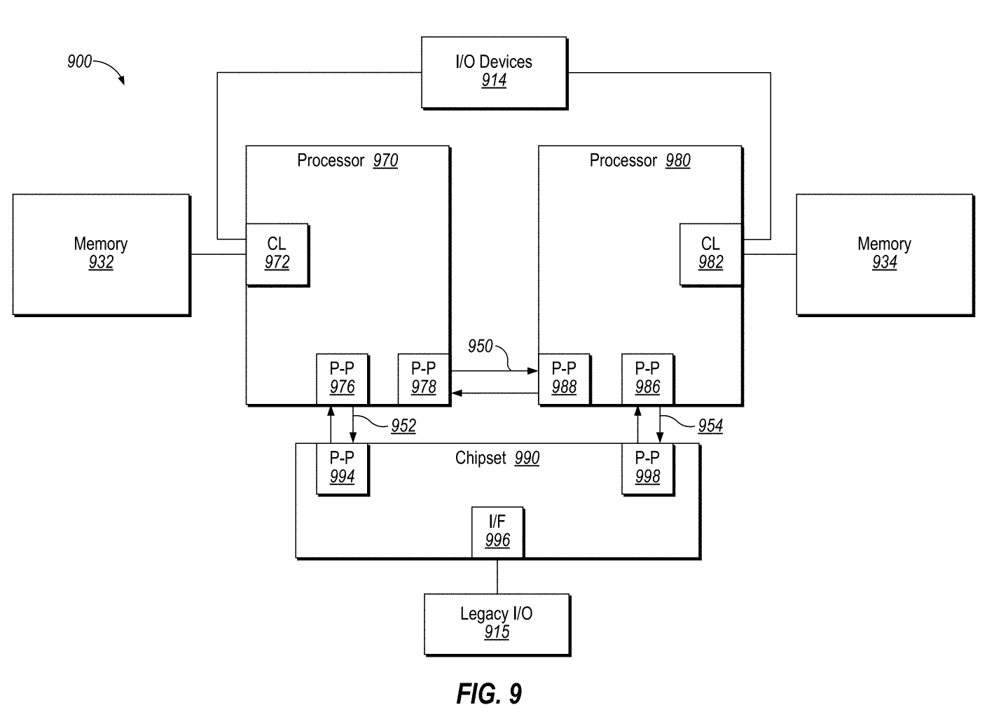

Referring now to FIG. 9, shown is a block diagram of a system 900 in which an embodiment of the disclosure may operate. FIG. 9 illustrates processors 970, 980. In one embodiment, processors 970, 980 may implement hybrid cores as described above. Processors 970, 980 may include integrated memory and I/O control logic (“CL”) 972 and 982, respectively and intercommunicate with each other via point-to-point interconnect 950 between point-to-point (P-P) interfaces 978 and 988 respectively. Processors 970, 980 each communicate with chipset 990 via point-to-point interconnects 952 and 954 through the respective P-P interfaces 976 to 994 and 986 to 998 as shown. For at least one embodiment, the CL 972, 982 may include integrated memory controller units. CLs 972, 982 may include I/O control logic. As depicted, memories 932, 934 coupled to CLs 972, 982 and I/O devices 914 are also coupled to the control logic 972, 982. Legacy I/O devices 915 are coupled to the chipset 990 via interface 996.

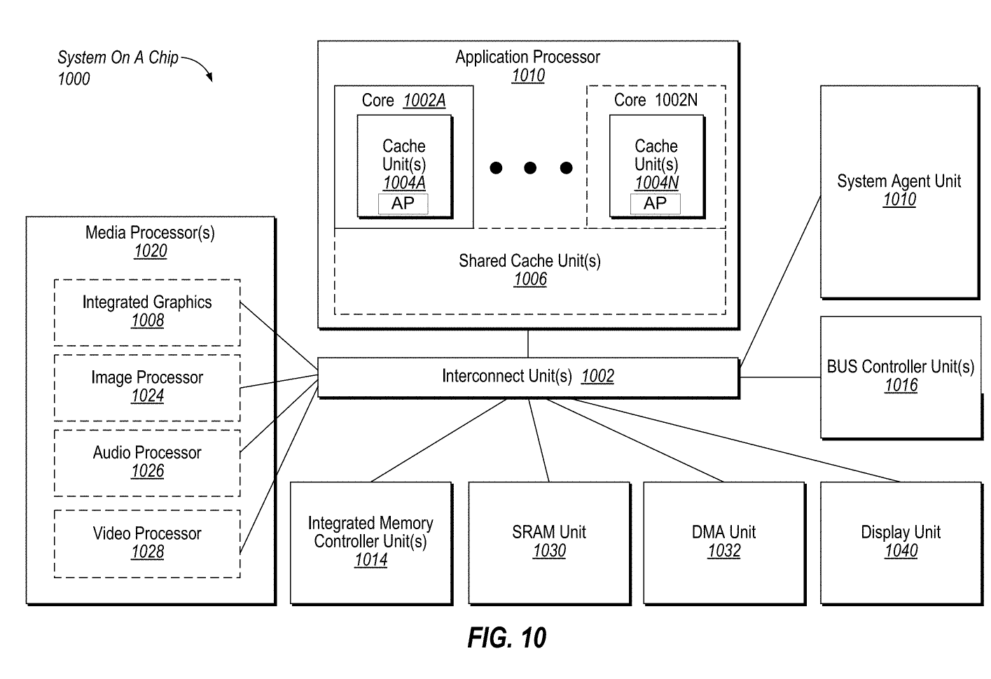

Embodiments may be implemented in many different system types. FIG. 10 is a block diagram of a SoC 1000 in accordance with an embodiment of the present disclosure. Dashed lined boxes are optional features on more advanced SoCs. In some implementations, SoC 1000 as shown in FIG. 10 includes features of the system 100 as shown in FIG. 1. In FIG. 10, an interconnect unit(s) 1012 is coupled to: an application processor 1020 which includes a set of one or more cores 1002A-N and shared cache unit(s) 1006; a system agent unit 1010; a bus controller unit(s) 1016; an integrated memory controller unit(s) 1014; a set or one or more media processors 1018 which may include integrated graphics logic 1008, an image processor 1024 for providing still and/or video camera functionality, an audio processor 1026 for providing hardware audio acceleration, and a video processor 1028 for providing video encode/decode acceleration; an static random access memory (SRAM) unit 1030; a direct memory access (DMA) unit 1032; and a display unit 1040 for coupling to one or more external displays. In one embodiment, a memory module may be included in the integrated memory controller unit(s) 1014. In another embodiment, the memory module may be included in one or more other components of the SoC 1000 that may be used to access and/or control a memory. The application processor 1020 may include a store address predictor for implementing hybrid cores as described in embodiments herein.

The memory hierarchy includes one or more levels of cache within the cores, a set or one or more shared cache units 1006, and external memory (not shown) coupled to the set of integrated memory controller units 1014. The set of shared cache units 1006 may include one or more mid-level caches, such as level 2 (L2), level 3 (L3), level 4 (L4), or other levels of cache, a last level cache (LLC), and/or combinations thereof.

In some embodiments, one or more of the cores 1002A-N are capable of multi-threading. The system agent 1010 includes those components coordinating and operating cores 1002A-N. The system agent unit 1010 may include for example a power control unit (PCU) and a display unit. The PCU may be or include logic and components needed for regulating the power state of the cores 1002A-N and the integrated graphics logic 1008. The display unit is for driving one or more externally connected displays.

The cores 1002A-N may be homogenous or heterogeneous in terms of architecture and/or instruction set. For example, some of the cores 1002A-N may be in order while others are out-of-order. As another example, two or more of the cores 1002A-N may be capable of execution the same instruction set, while others may be capable of executing only a subset of that instruction set or a different instruction set.

The application processor 1020 may be a general-purpose processor, such as a Core™ i3, i5, i7, 2 Duo and Quad, Xeon™, Itanium™, Atom™ or Quark™ processor, which are available from Intel™ Corporation, of Santa Clara, Calif. Alternatively, the application processor 1020 may be from another company, such as ARM Holdings™, Ltd, MIPS™, etc. The application processor 1020 may be a special-purpose processor, such as, for example, a network or communication processor, compression engine, graphics processor, co-processor, embedded processor, or the like. The application processor 1020 may be implemented on one or more chips. The application processor 1020 may be a part of and/or may be implemented on one or more substrates using any of a number of process technologies, such as, for example, BiCMOS, CMOS, or NMOS.

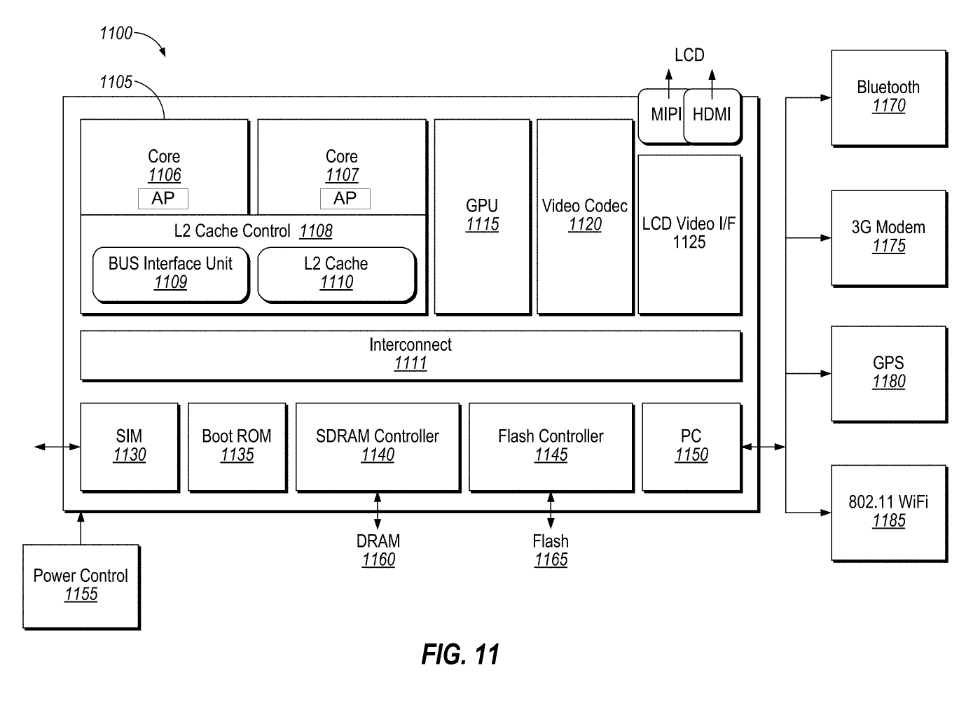

FIG. 11 is a block diagram of an embodiment of a system on-chip (SoC) design in accordance with the present disclosure. As a specific illustrative example, SoC 1100 is included in user equipment (UE). In one embodiment, UE refers to any device to be used by an end-user to communicate, such as a hand-held phone, smartphone, tablet, ultra-thin notebook, notebook with broadband adapter, or any other similar communication device. Often a UE connects to a base station or node, which potentially corresponds in nature to a mobile station (MS) in a GSM network.

Here, SOC 1100 includes 2 cores—1106 and 1107. Cores 1106 and 1107 may conform to an Instruction Set Architecture, such as an Intel® Architecture Core™-based processor, an Advanced Micro Devices, Inc. (AMD) processor, a MIPS-based processor, an ARM-based processor design, or a customer thereof, as well as their licensees or adopters. Cores 1106 and 1107 are coupled to cache control 1108 that is associated with bus interface unit 1109 and L2 cache 1110 to communicate with other parts of system 1100. Interconnect 1111 includes an on-chip interconnect, such as an IOSF, AMBA, or other interconnect discussed above, which potentially implements one or more aspects of the described disclosure. In one embodiment, cores 1106, 1107 may implement hybrid cores as described in embodiments herein.

Interconnect 1111 provides communication channels to the other components, such as a Subscriber Identity Module (SIM) 1130 to interface with a SIM card, a boot ROM 1135 to hold boot code for execution by cores 1106 and 1107 to initialize and boot SoC 1100, a SDRAM controller 1140 to interface with external memory (e.g. DRAM 1160), a flash controller 1145 to interface with non-volatile memory (e.g. Flash 1165), a peripheral control 1150 (e.g. Serial Peripheral Interface) to interface with peripherals, video codecs 1120 and Video interface 1125 to display and receive input (e.g. touch enabled input), GPU 1115 to perform graphics related computations, etc. Any of these interfaces may incorporate aspects of the disclosure described herein. In addition, the system 1100 illustrates peripherals for communication, such as a Bluetooth module 1170, 3G modem 1175, GPS 1180, and Wi-Fi 1185.

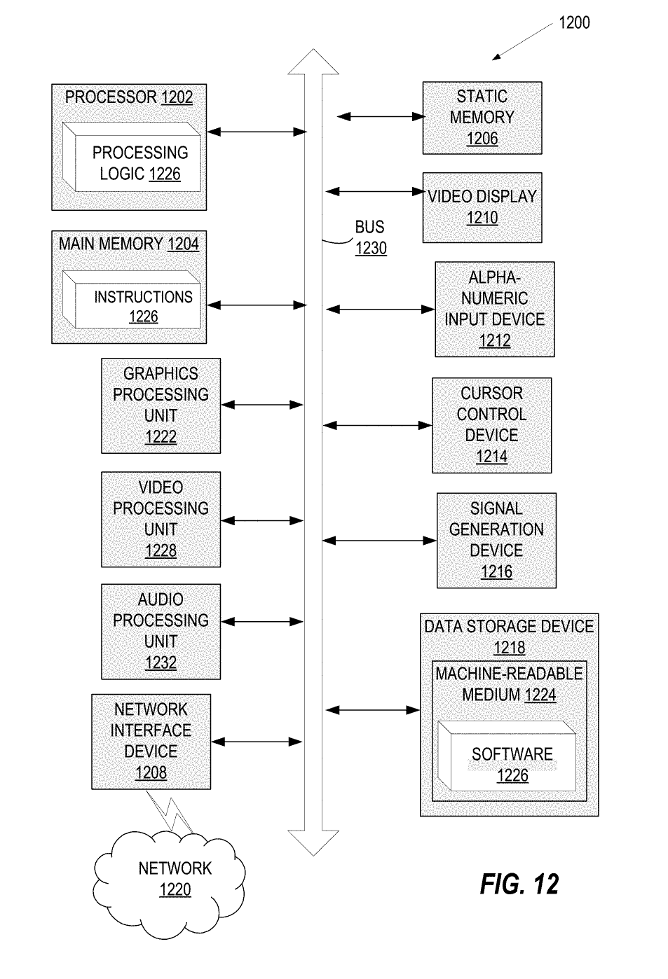

FIG. 12 illustrates a diagrammatic representation of a machine in the example form of a computer system 1200 within which a set of instructions, for causing the machine to perform any one or more of the methodologies discussed herein, may be executed. In alternative embodiments, the machine may be connected (e.g., networked) to other machines in a LAN, an intranet, an extranet, or the Internet. The machine may operate in the capacity of a server or a client device in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The computer system 1200 includes a processing device 1202, a main memory 1204 (e.g., read-only memory (ROM), flash memory, dynamic random access memory (DRAM) (such as synchronous DRAM (SDRAM) or DRAM (RDRAM), etc.), a static memory 1206 (e.g., flash memory, static random access memory (SRAM), etc.), and a data storage device 1218, which communicate with each other via a bus 1230.

Processing device 1202 represents one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. Processing device 1202 may also be one or more special-purpose processing devices such as an application specific integrated circuit (ASIC), a field programmable gate array (FPGA), a digital signal processor (DSP), network processor, or the like. In one embodiment, processing device 1202 may include one or more processing cores. The processing device 1202 is configured to execute the processing logic 1226 for performing the operations and steps discussed herein. For example, processing logic 1226 may perform operations as described in FIGS. 3 and 4. In one embodiment, processing device 1202 is the same as system 100 described with respect to FIG. 1 (and the same as system 200 described with respect to FIG. 2) as described herein with embodiments of the disclosure.

The computer system 1200 may further include a network interface device 1208 communicably coupled to a network 1220. The computer system 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), and a signal generation device 1216 (e.g., a speaker). Furthermore, computer system 1200 may include a graphics processing unit 1222, a video processing unit 1228, and an audio processing unit 1232.

The data storage device 1218 may include a machine-accessible storage medium 1224 on which is stored software 1226 implementing any one or more of the methodologies of functions described herein, such as implementing store address prediction for memory disambiguation as described above. The software 1226 may also reside, completely or at least partially, within the main memory 1204 as instructions 1226 and/or within the processing device 1202 as processing logic 1226 during execution thereof by the computer system 1200; the main memory 1204 and the processing device 1202 also constituting machine-accessible storage media.

The machine-readable storage medium 1224 may also be used to store instructions 1226 implementing store address prediction for hybrid cores such as described according to embodiments of the disclosure. While the machine-accessible storage medium 1128 is shown in an example embodiment to be a single medium, the term “machine-accessible storage medium” should be taken to include a single medium or multiple media (e.g., a centralized or distributed database, and/or associated caches and servers) that store the one or more sets of instructions. The term “machine-accessible storage medium” shall also be taken to include any medium that is capable of storing, encoding or carrying a set of instruction for execution by the machine and that cause the machine to perform any one or more of the methodologies of the present disclosure. The term “machine-accessible storage medium” shall accordingly be taken to include, but not be limited to, solid-state memories, and optical and magnetic media.

The following examples pertain to further embodiments. Example 1 is a multi-core processor comprising a first core, a second core, a first cache, a second cache, a third cache, and a cache controller unit is provided. The cache controller is operatively coupled to at least the first cache, the second cache, and the third cache. The cache controller is to evict a first line from the first cache, wherein the first core is in an active state. Responsive to the evicting of the first line, the first line is stored in the third cache. Responsive to storing the first line, a second line is evicted from the third cache. Responsive to evicting the second line, the second line is stored in the second cache when the second core is in an idle state.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘to,’ ‘capable of/to,’ and/or ‘operable to,’ in one embodiment, refers to some apparatus, logic, hardware, and/or element designed in such a way to enable use of the apparatus, logic, hardware, and/or element in a specified manner. Note as above that use of ‘to,’ ‘capable of/to,’ and/or ‘operable to,’ in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 910 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

1. A processing device comprising:
a package;
a plurality of dies disposed on the package, wherein each die comprises a clock receiver;
a single common clock source to generate a common clock signal; and
a clock distribution circuitry coupled to the single common clock source, the clock distribution circuitry to distribute the common clock signal from the single common clock source to each of the plurality of dies individually, wherein the clock distribution circuitry comprises:
a first group of terminated transmission lines, comprising:
a first terminated transmission line; and
a second terminated transmission line, wherein the first terminated transmission line and the second terminated transmission line receive the common clock signal from the single common clock source.

2. The processing device of claim 1, wherein the clock distribution circuitry further comprises:
a second group of terminated transmission lines coupled to the first terminated transmission line, wherein the second group of terminated transmission lines comprises:
a third terminated transmission line;
a fourth terminated transmission line, wherein the third terminated transmission line and the fourth terminated transmission line receive the common clock signal from the single common clock source; and
a second termination resistor coupled between the third terminated transmission line and the fourth terminated transmission line; and
a third group of terminated transmission lines coupled to the second terminated transmission line, wherein the third group of terminated transmission lines comprises:
a fifth terminated transmission line;
a sixth terminated transmission line, wherein the fifth terminated transmission line and the sixth terminated transmission line receive the common clock signal from the single common clock source; and
a third termination resistor coupled between the fifth terminated transmission line and the sixth terminated transmission line.

3. The processing device of claim 2, wherein the clock distribution circuitry further comprises:
a fourth group of terminated transmission lines coupled to the third terminated transmission line, wherein the fourth group of terminated transmission lines comprises:
a seventh terminated transmission line coupled to a clock receiver of a first die;
an eighth terminated transmission line coupled a clock receiver of a second die, wherein the seventh terminated transmission line and the eighth terminated transmission line receive the common clock signal from the single common clock source; and
a fourth terminated resistor coupled between the seventh terminated transmission line and the eighth terminated transmission line;
a fifth group of terminated transmission lines coupled to the fourth terminated transmission line, wherein the fifth group of terminated transmission lines comprises:
a ninth terminated transmission line coupled to a clock receiver of a third die;
an tenth terminated transmission line coupled a clock receiver of a fourth die, wherein the ninth terminated transmission line and the tenth terminated transmission line receive the common clock signal from the single common clock source; and
a fifth terminated resistor coupled between the ninth terminated transmission line and the tenth terminated transmission line;
a sixth group of terminated transmission lines coupled to the fifth terminated transmission line, wherein the sixth group of terminated transmission lines comprises:
an eleventh terminated transmission line coupled to a clock receiver of a fifth die;
a twelfth terminated transmission line coupled a clock receiver of a sixth die, wherein the eleventh terminated transmission line and the twelfth terminated transmission line receive the common clock signal from the single common clock source; and
a sixth terminated resistor coupled between the eleventh terminated transmission line and the twelfth terminated transmission line; and
a seventh group of terminated transmission lines coupled to the sixth terminated transmission line, wherein the seventh group of terminated transmission lines comprises:
a thirteenth terminated transmission line coupled to a clock receiver of a seventh die;
a fourteenth terminated transmission line coupled a clock receiver of an eighth die, wherein the thirteenth terminated transmission line and the fourteenth terminated transmission line receive the common clock signal from the single common clock source; and
a seventh terminated resistor coupled between the thirteenth terminated transmission line and the fourteenth terminated transmission line.

4. The processing device of claim 1, wherein the single common clock source is disposed at a center of the package.

5. The processing device of claim 1, wherein at least one die of the plurality of die is stacked on another die of the plurality of dies.

6. The processing device of claim 1, wherein the first and second transmission lines are differential transmission lines.

7. The processing device of claim 1, wherein the first and second transmission lines are single ended transmission lines.

8. The processing device of claim 1, wherein the common clock source is a phase-locked loop (PLL).

9. The processing device of claim 1, wherein the clock distribution circuitry comprises a fan-out buffer.

10. The processing device of claim 1, wherein the clock distribution circuitry further comprises a line driver coupled to the first terminated transmission line and the second terminated transmission line.

11. The processing device of claim 1, wherein the first group of terminated transmission lines further comprises:
a first termination resistor coupled between the first terminated transmission line and the second terminated transmission line.

12. A system comprising:
a package;
a core disposed on the package;
a plurality of dies disposed on the package, wherein each die comprises a clock receiver;
a single common clock source to generate a common clock signal; and
a clock distribution circuitry coupled to the single common clock source, the clock distribution circuitry to distribute the common clock signal from the single common clock source to each of the plurality of dies individually, wherein the clock distribution circuitry comprises:
a first group of terminated transmission lines, comprising:
a first terminated transmission line; and
a second terminated transmission line, wherein the first terminated transmission line and the second terminated transmission line receive the common clock signal from the single common clock source.

13. The system of claim 12, wherein the clock distribution circuitry further comprises:
a second group of terminated transmission lines coupled to the first terminated transmission line, wherein the second group of terminated transmission lines comprises:
a third terminated transmission line;
a fourth terminated transmission line, wherein the third terminated transmission line and the fourth terminated transmission line receive the common clock signal from the single common clock source; and
a second termination resistor coupled between the third terminated transmission line and the fourth terminated transmission line; and
a third group of terminated transmission lines coupled to the second terminated transmission line, wherein the third group of terminated transmission lines comprises:
a fifth terminated transmission line;
a sixth terminated transmission line, wherein the fifth terminated transmission line and the sixth terminated transmission line receive the common clock signal from the single common clock source; and
a third termination resistor coupled between the fifth terminated transmission line and the sixth terminated transmission line.

14. The system of claim 13, wherein the clock distribution circuitry further comprises:
a fourth group of terminated transmission lines coupled to the third terminated transmission line, wherein the fourth group of terminated transmission lines comprises:
a seventh terminated transmission line coupled to a clock receiver of a first die;
an eighth terminated transmission line coupled a clock receiver of a second die, wherein the seventh terminated transmission line and the eighth terminated transmission line receive the common clock signal from the single common clock source; and
a fourth terminated resistor coupled between the seventh terminated transmission line and the eighth terminated transmission line;
a fifth group of terminated transmission lines coupled to the fourth terminated transmission line, wherein the fifth group of terminated transmission lines comprises:
a ninth terminated transmission line coupled to a clock receiver of a third die;
an tenth terminated transmission line coupled a clock receiver of a fourth die, wherein the ninth terminated transmission line and the tenth terminated transmission line receive the common clock signal from the single common clock source; and
a fifth terminated resistor coupled between the ninth terminated transmission line and the tenth terminated transmission line;
a sixth group of terminated transmission lines coupled to the fifth terminated transmission line, wherein the sixth group of terminated transmission lines comprises:
an eleventh terminated transmission line coupled to a clock receiver of a fifth die;
a twelfth terminated transmission line coupled a clock receiver of a sixth die, wherein the eleventh terminated transmission line and the twelfth terminated transmission line receive the common clock signal from the single common clock source; and
a sixth terminated resistor coupled between the eleventh terminated transmission line and the twelfth terminated transmission line; and
a seventh group of terminated transmission lines coupled to the sixth terminated transmission line, wherein the seventh group of terminated transmission lines comprises:
a thirteenth terminated transmission line coupled to a clock receiver of a seventh die;
a fourteenth terminated transmission line coupled a clock receiver of an eighth die, wherein the thirteenth terminated transmission line and the fourteenth terminated transmission line receive the common clock signal from the single common clock source; and
a seventh terminated resistor coupled between the thirteenth terminated transmission line and the fourteenth terminated transmission line.

15. The system of claim 12, wherein the single common clock source is disposed at a center of the package.

16. The system of claim 12, wherein at least one die of the plurality of die is stacked on another die of the plurality of dies.

17. The system of claim 12, wherein the first and second transmission lines are differential transmission lines.

18. The system of claim 12, wherein the first and second transmission lines are single ended transmission lines.

19. The system of claim 12, wherein the common clock source is a phase-locked loop (PLL).

20. The system of claim 12, wherein the clock distribution circuitry comprises a fan-out buffer.

21. The system of claim 12, wherein the clock distribution circuitry further comprises a line driver coupled to the first terminated transmission line and the second terminated transmission line.

22. A clock distribution circuit comprising:
an input terminal coupled to receive a clock signal from a single common clock source;
a line driver coupled to the input terminal;
a plurality of output terminals, each output terminal being located at a die site disposed on a same package;
a first pair of transmission lines comprising a first terminated transmission line and a second terminated transmission line;
a first termination resistor coupled between the first transmission line and the second transmission line;
a second pair of transmission lines coupled to the first transmission line;
a second termination resistor coupled between the second pair of transmission lines;
a third pair of transmission lines coupled to the second transmission line; and
a third termination resistor coupled between the third pair of transmission lines, wherein each of the transmission lines of the second pair and the third pair is coupled to one of the plurality of output terminals.

23. The clock distribution circuit of claim 22, further comprising:
a fourth pair of transmission lines coupled to one of the second pair of transmission lines;
a fourth termination resistor coupled between the fourth pair of transmission lines;
a fifth pair of transmission lines coupled to another one of the second pair of transmission lines;
a fifth termination resistor coupled between the fifth pair of transmission lines;
a sixth pair of transmission lines coupled to one of the third pair of transmission lines;
a sixth termination resistor coupled between the sixth pair of transmission lines;
a seventh pair of transmission lines coupled to another one of the third pair of transmission lines; and
a seventh termination resistor coupled between the seventh pair of transmission lines, wherein each of the transmission lines of the fourth pair, fifth pair, sixth pair, and seventh pair is coupled to one of the plurality of output terminals.
